(19) United States
(12) Patent Application Publication
(10) Pub. No.: US 2023/0099190 A1
(43) Pub. Date: Mar. 30, 2023

(54) DISPLAY PANEL, MANUFACTURING METHOD THEREOF AND DISPLAY APPARATUS

(71) Applicant: Wuhan China Star Optoelectronics Technology Co., Ltd., Wuhan, Hubei (CN)

(72) Inventors: Li ZHONG, Wuhan, Hubei (CN); Guowei ZHA, Wuhan, Hubei (CN)

(73) Assignee: Wuhan China Star Optoelectronics Technology Co., Ltd., Wuhan, Hubei (CN)

(21) Appl. No.: 16/975,710

(22) PCT Filed: Jul. 21, 2020
(86) PCT No.: PCT/CN2020/103180

§ 371 Date: Aug. 26, 2020

(30) Foreign Application Priority Data
Jun. 19, 2020 (CN) 202010566417.X

(51) Int. Cl. G02F 1/1362

(52) U.S. Cl. CPC G02F 1/136295; G02F 1/136222

(57) ABSTRACT

A display panel, a manufacturing method thereof, and a display apparatus are provided. The display panel includes a first display region; a plurality of first pixel units, wherein each of the first pixel units includes a light-transmitting region and a light-emitting device; a first substrate including a first portion for mounting the light-emitting device. A plurality of electrodes of the light-emitting device are electrically connected to a first driving circuit by an electric connecting wire, so that the under-screen sensing technique overlapping the optical display in space of the display panel is achieved, and a thickness of the display panel is reduced.

### FIELD DISCLOSURE

The present disclosure relates to the technical field of displays, and in particular to a display panel, a manufacturing method thereof, and a display apparatus.

### BACKGROUND OF DISCLOSURE

A display apparatus with a high screen-to-body ratio may bring desirable experience for consumers, and has become the research focus in the field of display due to a narrow screen bezel and a large display area. However, the existing display apparatuses cannot display in a region where sensors disposed because the under-screen sensing technique cannot overlap the optical display in space of the existing full-screen display apparatuses. Moreover, in order to achieve the under-screen sensing technique, a thickness of the display apparatus must be affected, which is disadvantageous for user experience. Therefore, how to achieve a real full-screen display in the display apparatus and reduce the thickness of the display apparatus has become a hot issue for research.

### SUMMARY OF INVENTION

### Technical Problems

A display panel, a manufacturing method, and a display apparatus are provided in an embodiment of the present disclosure, which may solve the problems that the under-screen sensing technique cannot overlap the optical display in space, and the display apparatus is thick.

### Technical Solutions

A display panel including a first display region is provided in an embodiment of the present disclosure. The display panel includes:

a plurality of first pixel units located within the first display region, wherein each of the first pixel units includes a light-transmitting region and a light-emitting device disposed adjacent to the light-transmitting region;

a first substrate including a first portion located within the first display region, wherein the first portion includes a first driving circuit and an electric connecting wire located on the first driving circuit;

wherein the light-emitting device is mounted on the first portion, the light-emitting device includes a plurality of electrodes away from the first driving circuit, and each of the electrodes is electrically connected to the first driving circuit by the electric connecting wire.

In the display panel, the light-emitting device includes at least one of a mini light-emitting diode and a micro light-emitting diode.

In the display panel, the light-emitting device further includes a main body mounted on the first substrate, the electrodes extended from the main body, and the electric connecting wire extended along a surface of the main body.

In the display panel, each of the electrodes includes a first electrode and a second electrode extended from the main body. The electric connecting wire includes a first wire and a second wire, the first wire electrically connects the first electrode with the first driving circuit, and the first wire is extended along the surface of the main body. The second wire electrically connects the second electrode with the first driving circuit, and the second wire is extended along the surface of the main body

In the display panel, a manufacturing material of the electric connecting wire includes one of titanium (Ti), aluminum (Al), molybdenum (Mo), and indium tin oxide (ITO).

In the display panel, a size of a section of the electric connecting wire is greater than or equal to 100 nm and less than or equal to 1000 nm.

In the display panel, the display panel further includes a second display region arranged adjacent to the first display region, and the display panel further includes a plurality of second pixel units located within the second display region, wherein a luminous mode of the second pixel units is different from a luminous of the first pixel units.

In the display panel, each of the second pixel units is a liquid crystal display pixel unit.

In the display panel, the first substrate further includes a second portion located within the second display region. The second portion includes a second driving circuit, and the second driving circuit is used to drive the second pixel units.

In the display panel, the electric connecting wire is located in the same layer with a conductive layer of the second driving circuit, and a material of the electric connecting wire is the same as a material of the conductive layer.

In the display panel, the conductive layer includes a pixel electrode, and the electric connecting wire is located in the same layer with the pixel electrode and the material of the conductive layer is the same as a material of the pixel electrode.

In the display panel, the display panel further includes a second substrate disposed opposite the first substrate, and a portion of the second substrate corresponding to the second portion includes a plurality of color filter units.

In the display panel, the display panel further includes:

a first polarizer disposed on a side of the first substrate away from the second substrate, wherein a portion of the first polarizer corresponding to the first portion is provided with a plurality of through-holes; and

a second polarizer disposed on a side of the second substrate away from the first substrate.

In the display panel, the display panel further includes: a backlight module disposed on a side of the first polarizer away from the first substrate, wherein a portion of the backlight module corresponding to the first portion is provided with the plurality of through-holes.

In the display panel, in a top viewing angle, an area of the light-emitting device is less than or equal to an area of the light-transmitting region

A manufacturing method for a display panel is further provided in the present disclosure. The manufacturing method includes steps as below:

S10, forming a first substrate, wherein the first substrate includes a first portion and a second portion adjacent to the first portion, the first portion includes a first driving circuit, and the second portion includes a second driving circuit;

S20, forming a light-emitting device on the first portion, wherein the light-emitting device includes a plurality of electrodes away from the first driving circuit; and

S30, forming an electric connecting wire by a deposition process, wherein the electric connecting wire electrically connects the electrodes with the first driving circuit.

The first portion of the first substrate corresponds to a first display region of the display panel, the second portion of the first substrate corresponds to a second display region of the display panel adjacent to the first portion, and the display panel includes a plurality of first pixel units located within the first display region, and a plurality of second pixel units located within the second display region. A luminous mode of the first pixel units is different from a luminous mode of the second pixel units, each of the first pixel units includes a light-transmitting region and a light-emitting device disposed adjacent to the light-transmitting region, and the second pixel units are driven by the second driving circuit.

In the manufacturing method, the light-emitting device includes at least one of a mini light-emitting diode and a micro light-emitting diode.

A display apparatus including the display panel and a sensor is further provided in the present disclosure. The display panel includes:

a plurality of first pixel units located within a first display region, wherein each of the first pixel units includes a light-transmitting region and a light-emitting device disposed adjacent to the light-transmitting region;

a first substrate including a first portion located within the first display region, wherein the first portion includes a first driving circuit and an electric connecting wire located on the first driving circuit;

wherein the light-emitting device is mounted on the first portion, the light-emitting device includes a plurality of electrodes away from the first driving circuit, and each of the electrodes is electrically connected to the first driving circuit by the electric connecting wire; and the sensor faces to the first display region.

In the display apparatus, the sensor includes at least one of a fingerprint recognition sensor, a camera, a structured light sensor, a time of flight sensor, a distance sensor, and a light sensor.

### Beneficial Effects

Compared with the existing technique, a display panel, a manufacturing method thereof, and a display apparatus are provided in an embodiment of the present disclosure. The display panel includes a first display region. The display panel includes: a plurality of first pixel units located within the first display region, wherein each of the first pixel units includes a light-transmitting region and a light-emitting device disposed adjacent to the light-transmitting region; a first substrate including a first portion located within the first display region, wherein the first portion includes a first driving circuit and an electric connecting wire located on the first driving circuit. The light-emitting device is mounted on the first portion, the light-emitting device includes a plurality of electrodes away from the first driving circuit, and each of the electrodes is electrically connected to the first driving circuit by the electric connecting wire, so that the under-screen sensing technique overlapping the optical display in space of the display panel is achieved, and a thickness of the display panel is reduced. In the display apparatus manufactured by the display panel, the under-screen sensing technique overlapping the optical display in space of the display panel is also achieved, and a thickness of the display panel is also reduced.

### BRIEF DESCRIPTION OF DRAWINGS

FIGS. 1A-1C are schematic views of structures of a display panel provided by embodiments of the present disclosure.

FIGS. 1D-1E are schematic views of structures of a first portion of a first substrate provided by embodiments of the present disclosure.

FIGS. 2A-2B are top views of first pixel units provided by embodiments of the present disclosure.

FIGS. 3A-3F are top views of a display panel provided by embodiments of the present disclosure.

FIG. 4 is a manufacturing flow chart of a display panel provided by an embodiment of the present disclosure.

FIGS. 5A-5D are schematic views of the manufacturing process of a display panel provided by embodiments of the present disclosure.

FIG. 6 is a schematic view of a structure of a display apparatus provided by an embodiment of the present disclosure.

The reference numerals are identified as below:

100a. first display region; 100b. second display region; 102a. first portion; 102b. second portion; 101a. first sub-pixel; 1012a. electrode; 1012b. first electrode; 1012c. second electrode; 1013a. first color-conversion unit; 1013b. second color-conversion unit; 1041a. sub color filter unit; 1022a. first wire; 1022b. second wire; 1012d. main body; 1012e. light-emitting device; 101. First pixel unit; 1011. light-transmitting region; 1012. light-emitting device; 1013. color-conversion film; 102. first substrate; 1021. first driving circuit; 1022. electric connecting wire; 1023. second driving circuit; 103. second pixel unit; 104. second substrate; 1041. color filter unit; 1051. first polarizer; 1052. second polarizer; 106. liquid crystal molecule; 107. sealant; 108. Backlight module; 601. sensor.

### DETAILED DESCRIPTION OF EMBODIMENTS

The technical solutions in the embodiments of the present disclosure are clearly and completely described in the following description, which is combined with the drawings in the embodiments of the present disclosure. It is noted that the described embodiments are only used to explain the present disclosure, not used to limit the present disclosure.

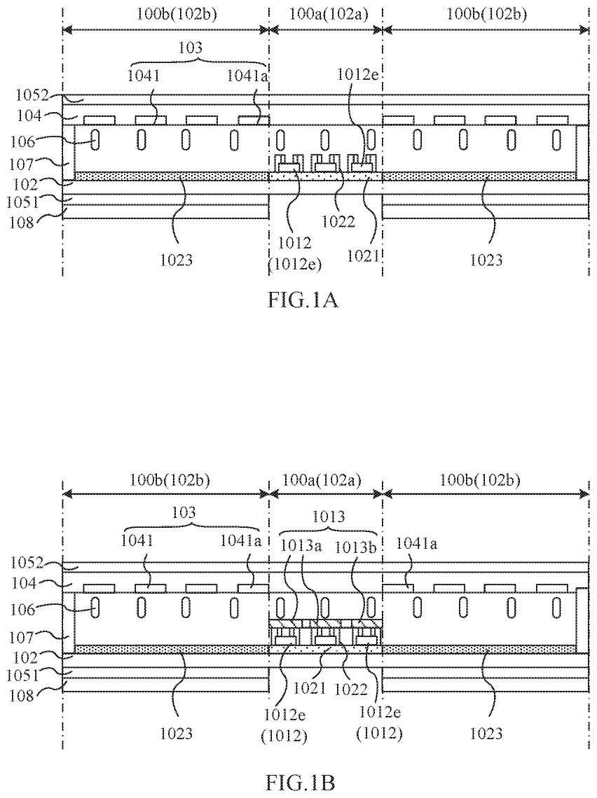

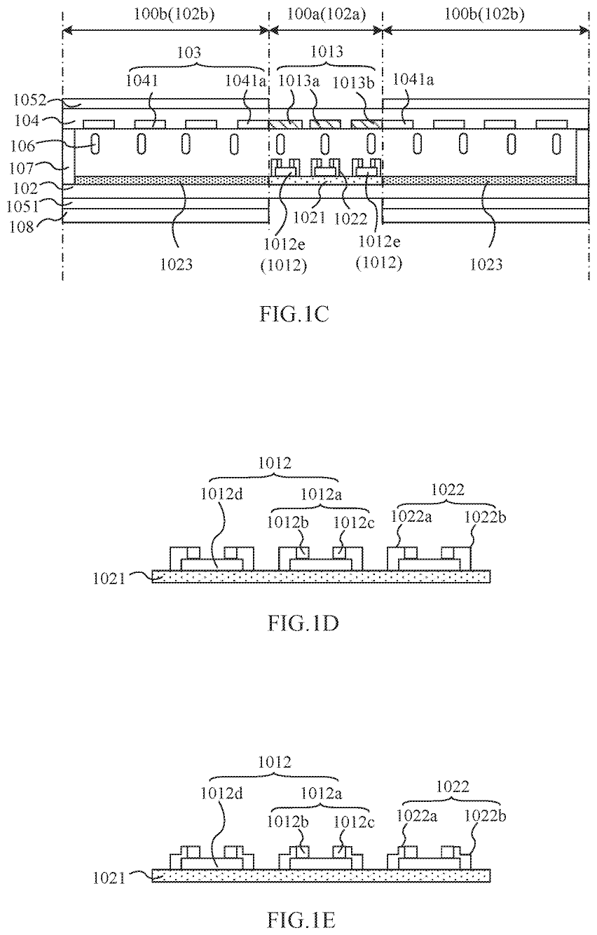

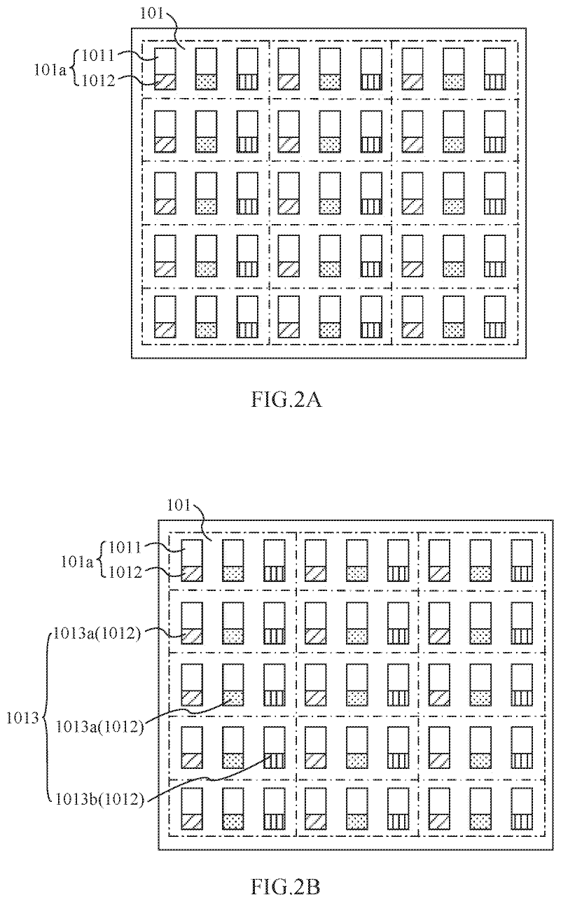

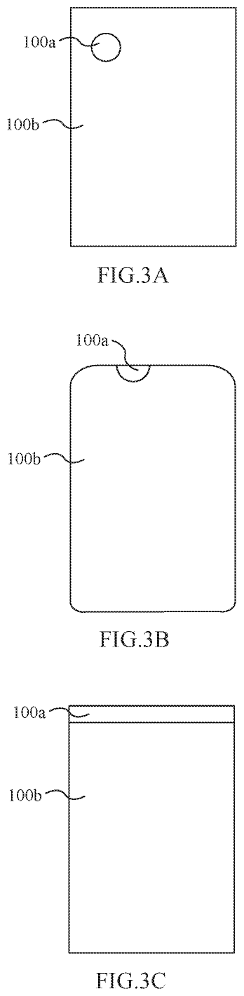

Specifically, please refer to FIGS. 1A-1C which are are schematic views of structures of a display panel provided by embodiments of the present disclosure. Refer to FIGS. 1D-1E, which are schematic views of structures of a first portion of a first substrate provided by embodiments of the present disclosure. Refer to FIGS. 2A-2B, which are top views of first pixel units provided by embodiments of the present disclosure. Refer to FIGS. 3A-3F, which are top views of a display panel provided by embodiments of the present disclosure. The display panel includes a first display region 100a. The display panel includes:

a plurality of first pixel units 101 located within the first display region 100a, wherein each of the first pixel units 101 includes a light-transmitting region 1011 and a light-emitting device 1012 disposed adjacent to the light-transmitting region 1011; and

a first substrate 102 including a first portion 102a located within the first display region 100a, wherein the first portion 102a includes a first driving circuit 1021 and an electric connecting wire 1022 located on the first driving circuit 1021.

The light-emitting device 1012 is mounted on the first portion 102a, the light-emitting device 1012 includes a plurality of electrodes 1012a away from the first driving circuit 1021, and each of the electrodes 1012a is electrically connected to the first driving circuit 1021 by the electric connecting wire 1022.

Because each of the first pixel units 101 includes the light-transmitting region 1011 and the light-emitting device, the first display region 100a has a certain transmittance by the light-transmitting region 1011. The light-transmitting region 1011 may be a channel providing signal transmission for achieving the under-screen sensing technique. The light-emitting device 1012 may ensure the normal display of the first pixel units 101, so as to achieve the under-screen sensing technique overlapping the optical display in space of the display panel, and facilitate realizing a full-screen design.

In order to make the display panel have a transparent display function within the first display region 100a, in a top viewing angle, an area of the light-emitting device 1012 is less than or equal to an area of the light-transmitting region 1011, so that the first display region 100a has a certain light transmittance, as shown in FIGS. 2A-2B.

Specifically, each of the first pixel units 101 includes a plurality of first sub-pixels 101a, and each of the first sub-pixels 101a includes the light-transmitting region 1011 and the light-emitting device 1012. In each of the first sub-pixels 101a, an area of the light-transmitting region 1011 is 50% to 99% of an area of the first sub-pixel 101a.

Further, a size of each of the light-emitting device 1012 is greater than or equal to 1 μm and less than or equal to 500 μm. A size of each of the first sub-pixels 101a is greater than or equal to 10 μm and less than or equal to 1000 μm, wherein the size of the light-emitting device 1012 means a length and a width of the light-emitting device 1012 in the top viewing angle. Similarly, the size of the first sub-pixel 101a means a length and a width of the first sub-pixel 101a in the top viewing angle.

Please continue to refer to FIGS. 1A-1C and FIGS. 2A-2B. The light-emitting device 1012 is a self-illuminating display device. Specifically, the light-emitting device 1012 includes at least one of a mini light-emitting diode and a micro light-emitting diode. Further, the light-emitting device 1012 is the micro light-emitting diode, so that display quality of the first display region 100a is not affected when the area for light-emitting of the first display region 100a is small. The light-emitting device 1012 is disposed within the first portion 102a of the first substrate 102 in a built-in form, which may avoid the problem of unstable display within the first display region 100a of the display panel when the light-emitting device 1012 is disposed in an external-mounting form.

Please continue to refer to FIGS. 1A-1C and FIGS. 1D-1E. The light-emitting device 1012 further includes a main body 1012d mounted on the first substrate 102, the electrodes 1012a extend from the main body 1012d, and the electric connecting wire 1022 extends along a surface of the main body 1012d. A size of the section of the electric connecting wire 1022 is greater than or equal to 100 nm and less than or equal to 1000 nm, so as to reduce the thickness of the display panel.

Further, each of the electrodes 1012a includes a first electrode 1012b and a second electrode 1012c extending from the main body 1012d. The electric connecting wire 1022 includes a first wire 1022a and a second wire 1022b, the first wire 1022a electrically connects the first electrode 1012b with the first driving circuit 1021, and the first wire 1022a extends along the surface of the main body 1012d. The second wire 1022b electrically connects the second electrode 1012c with the first driving circuit 1021, and the second wire 1022b extends along the surface of the main body 1012d.

A manufacturing material of the electric connecting wire 1022 includes at least one of titanium (Ti), aluminum (Al), molybdenum (Mo), and indium tin oxide (ITO). Further, in order to prevent the light transmittance of the first display region 100a from being affected by the electric connecting wire 1022, the manufacturing material of the electric connecting wire 1022 is a transparent metal material, wherein the transparent metal material includes indium tin oxide. Further, a manufacturing material of the electrodes 1012a is the same as the manufacturing material of the electric connecting wire 1022. Specifically, the manufacturing material of the electrodes 1012a is the transparent metal material, wherein the transparent metal material includes indium tin oxide, so that the high light transmittance of the first display region 100a is ensured.

Please continue to refer to FIGS. 1A-1C. The display panel further includes a second display region 100b arranged adjacent to the first display region 100a, and the display panel further includes a plurality of second pixel units 103 located within the second display region 100b, wherein a luminous mode of the second pixel units 103 is different from a luminous mode of the first pixel units 101.

Specifically, each of the second pixel units 103 is a liquid crystal display pixel unit.

The first substrate 102 further includes a second portion 102b located within the second display region 100b. The second portion 102b includes a second driving circuit 1023, and the second driving circuit 1023 is used to drive the second pixel units 103.

In order to simplify the manufacturing process, the electric connecting wire 1022 is located in the same layer with a conductive layer of the second driving circuit 1023, and a material of the electric connecting wire 1022 is the same as a material of the conductive layer. Further, the conductive layer includes a pixel electrode, the electric connecting wire 1022 is located in the same layer with the pixel electrode, and the material of the electric connecting wire 1022 is the same as a material of the pixel electrode.

The display panel further includes a second substrate 104 disposed opposite the first substrate 102, and a portion of the second substrate 104 corresponding to the second portion 102b includes a plurality of color filter units 1041, as shown in FIG. 1A.

In the display panel shown in FIG. 1A, the light-emitting device 1012 includes a red light-emitting device, a green light-emitting device, a blue light-emitting device, etc., so as to realize a full-color display of the display panel.

If a light emitted by the light-emitting devices 1012 is monochromatic light, the full-color display of the display panel may be realized by a color-conversion film.

Specifically, please continue to refer to FIG. 1B and FIG. 1C. The display panel further includes a color-conversion film 1013 located on a side of the light-emitting device 1012 away from the first substrate 102. The color-conversion film 1013 includes a first color-conversion unit 1013a and a second color-conversion unit 1013b. The first color-conversion unit 1013a converts light in a first wavelength emitted by the light-emitting device to light in a second wavelength, and the second color-conversion unit 1013b is used to transmit the light emitted by the light-emitting device 1012. That is, if the light-emitting device 1012 is the blue light-emitting device, the first color-conversion unit 1013a absorbs the light emitted by the light-emitting device 1012, such as blue light, red light, green light, orange light, and yellow light, and the second color-conversion unit 1013b transmits the blue light emitted by the light-emitting device.

Further, lights emitted by the light-emitting device 1012 and absorbed by the first color-conversion units 1013a may be different. That is, the first color-conversion unit 1013a further includes a first sub color-conversion unit and a second color-conversion unit, wherein the light emitted by the light-emitting device 1012 and absorbed by the first sub color-conversion unit is different from the light emitted by the light-emitting device 1012 and absorbed by the second sub color-conversion unit.

In order to simplify the manufacturing process, the color-conversion film 1013 may be located in the second substrate 104. Further, the first color-conversion unit 1013a and the second color-conversion unit 1013b of the color-conversion film 1013 may be manufactured in the same layer with the color-filter units 1041 on the second substrate 104. That is, a portion of the second substrate 104 corresponding to the first portion 102a includes the first color-conversion unit 1013a and the second color-conversion unit 1013b, as shown in the FIG. 1C.

In order to prevent the light-transmitting region 1011 from being covered by the color-conversion film 1013 and affecting the transmission, areas of the first color-conversion unit 1013a and the second transmission unit 1013b in the color-conversion film 1013 is equal to the area of the light-emitting device 1012. Moreover, in the top viewing angle, the first color-conversion unit 1013a and the second color-conversion unit 1013b cover the corresponding light-emitting devices 1012 respectively, as shown in FIG. 2B.

Please continue to refer to FIGS. 1A-1C. In order to avoid the problems that the display interruption, the display discontinuity, etc. occur at a junction of the first display region 100a and the second display region 100b, the first pixel unit 101 and the second pixel unit 103 are arranged adjacent to each other at the junction of the first display region 100a and the second display region 100b.

Specifically, the second pixel unit 103 includes the corresponding color filter unit 1041. In the top viewing angle, the first pixel unit 101 connects the color filter unit 1041 at the junction of the first display region 100a and the second display region 100b.

Further, in the display panel shown in FIG. 1A, a color of a sub color filter unit 1041a located adjacent to the junction of the first display region 100a and the second display region 100b in the color filter unit 1041 is the same as a color of the light-emitting device 1012e adjacent to the junction of the first display region 100a and the second display region 100b in the light-emitting device 1012. That is, if the sub color filter unit 1041a is a red color filter unit, the light-emitting device 1012e is a red light-emitting device. Similarly, in the display panel shown in FIGS. 1B-1C, a color of a sub color filter unit 1041a located adjacent to the junction of the first display region 100a and the second display region 100b in the color filter unit 1041 is the same as a color of the first color-conversion unit 1013a or the second color conversion unit 1013b adjacent to the junction of the first display region 100a and the second display region 100b in the color-conversion film 1013.

Please continue to refer to FIGS. 1A-1C. The display panel further includes:

a first polarizer 1051 disposed on a side of the first substrate 102 away from the second substrate 104, wherein a portion of the first polarizer 1051 corresponding to the first portion 102a is provided with a plurality of through-holes; and

a second polarizer 1052 disposed on a side of the second substrate 104 away from the first substrate 102.

The display panel further includes a plurality of liquid crystal molecules 106 and a sealant 107 located between the first substrate 102 and the second substrate 104.

Because the first polarizer 1051 is provided with through-holes on the portion corresponding to the first portion 102a, the liquid crystal molecules 1061 change the polarization state of the light within the first display region 100a but the dimming function cannot be achieved since the liquid crystal molecules 1061 are only affected by the second polarizer 1052. Therefore, the liquid crystal molecules 1061 do not affect the display of the first display region 100a.

It is understood that a portion of the second polarizer 1052 corresponding to the first portion 102a may also provide with the through-holes, as shown in FIG. 1C.

Please continue to refer to FIGS. 1A-1C. The display panel further includes:

a backlight module 108 disposed on a side of the first polarizer 1051 away from the first substrate 102, wherein a portion of the backlight module 108 corresponding to the first portion 102a is provided with the plurality of through-holes.

Please continue to refer to FIGS. 1A-1C. In order to ensure the light transmittance of the light-transmitting region, a manufacturing material of the first substrate 102 is the material with high light transmittance, such as glasses, colorless polyimide materials, and acrylic materials.

The first substrate 102 further includes a base, a buffer layer, etc. which are not shown. The first driving circuit 1021 further includes a first thin film transistor, a first control circuit, etc. which are not shown. The second driving circuit 1023 further includes a second thin film transistor, a second control circuit, etc. which are not shown.

The mode that the first driving circuit 1021 driving the light-emitting device 1012 includes an active matrix mode and a passive matrix mode. Specifically, the active matrix mode includes driving modes adopting low temperature poly-silicon technique, amorphous silicon technique, and indium gallium zinc oxide technique. In a case of a small area of the first display region 100a (for example, less than 10 mm×10 mm), the first driving circuit 1021 drives the light-emitting device 1012 in the passive matrix mode, so that a high light transmittance of the display panel is obtained.

Because the first display region 100a and the second display region 100b display in different luminous modes, the size of the first thin film transistor may be different from the size of the second thin film transistor. The size of the first thin film transistor and the second thin film transistor may be obtained by photoelectric matching according to the design requirements of the first display region 100a and the second display region 100b respectively, which are not redundantly described here.

The difference in display brightness between the first display region 100a and the second display region 100b may be matched in brightness according to the subsequent software algorithm. The difference in display accuracy between the first display region 100a and the second display region 100b may be optimized by the matching design of the resolution, which is not redundantly described here.

In the display panel shown in the FIGS. 1A-1C, the examples that the luminous mode of the second pixel units 103 differs from the luminous mode of the first pixel units 101 are described. It is understood that each of the second pixel units 103 may be applied in the same luminous mode of the first pixel units 101. That is, each of the second pixel units 103 includes a plurality of the second light-emitting devices, wherein the second light-emitting device is at least one of an organic light-emitting diode, a mini light-emitting diode and a micro light-emitting diode.

Further, in the junction of the first display region 100a and the second display region 100b, each of the first pixel units 101 is arranged adjacent to each of the second pixel units 103.

Specifically, in the top viewing angle, each of the first pixel units 101 is connected to each of the second pixel units 103 at the junction of the first display region 100a and the second display region 100b.

Further, the color of the second sub light-emitting device in the second light-emitting device near the junction of the first display region 100a and the second display region 100b is the same as the color of the light-emitting device 1012e in the light-emitting device 1012 near the junction of the first display region 100a and the second display region 100b. That is, if the second sub light-emitting device is the green light-emitting device, the light-emitting device is also the green light-emitting device.

Please continue to refer to FIGS. 3A-3F. At the top viewing angle, the first display region 100a may be located on the display panel, and may be also located below the display panel. The position of the first display region 100a may be designed according to the actual design requirements, which are not redundantly described here.

At the top viewing angle, the shape of the first display region includes one of circle, polygon, and combination thereof. The specific shape of the first display region may be designed according to the actual design requirements, which are not redundantly described here.

Furthermore, the display panel may also include a plurality of the first display regions 100a, and the first display regions 100a are disposed adjacent to the second display region 100b. The specific arranging mode of the first display regions 100a may be designed according to the actual design requirements, which are not redundantly described here.

The shape of the display panel, and the shape, the position, etc. of the first display region 100a and the second display region 100b shown in FIGS. 3A-3F are exemplary descriptions, which are not used to limit the present disclosure. Those skilled in the art may design according to the actual design requirements.

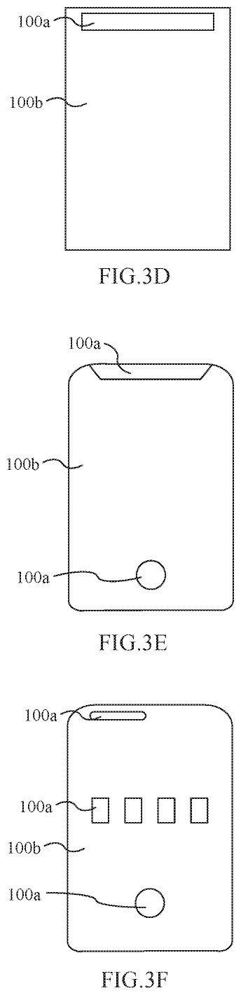

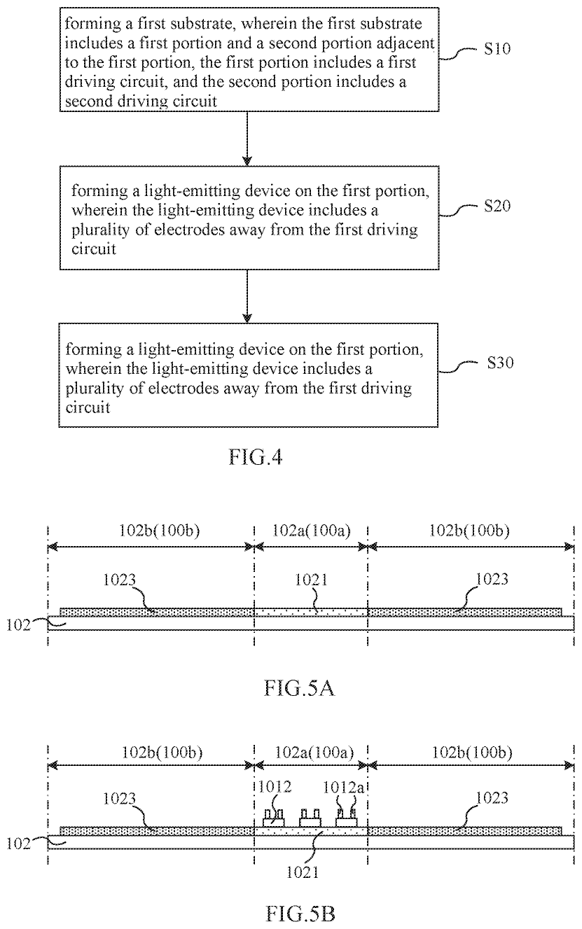

Please refer to FIG. 4, which is a manufacturing flow chart of a display panel provided by an embodiment of the present disclosure. Refer to FIGS. 5A-5D which are schematic views of the manufacturing process of a display panel provided by embodiments of the present disclosure.

A manufacturing method for a display panel is further provided in the present disclosure. The manufacturing method includes steps as below:

In step S10, forming a first substrate 102, wherein the first substrate 102 includes a first portion 102a and a second portion 102b adjacent to the first portion 102a, the first portion 102a includes a first driving circuit 1021, and the second portion 102b includes a second driving circuit 1023, as shown in FIG. 5;

In step S20, forming a light-emitting device 1012 on the first portion 102a, wherein the light-emitting device 1012 includes a plurality of electrodes 1012a away from the first driving circuit 1021, as shown in FIG. 5B; and

In step S30, forming an electric connecting wire 1022 by a deposition process, wherein the electric connecting wire 1022 electrically connects the electrodes 1012a with the first driving circuit 1021, as shown in FIG. 5C.

The first portion 102a of the first substrate 102 corresponds to a first display region 100a of the display panel, and the second portion 100b of the first substrate 102 corresponds to a second display region 100b of the display panel adjacent to the first display region 100a. The display panel includes a plurality of first pixel units located within the first display region 100a, and a plurality of second pixel units 103 located within the second display region 100b. A luminous mode of the first pixel units is different from a luminous mode of the second pixel units 103, each of the first pixel units includes a light-transmitting region 1011 and a light-emitting device 1012 disposed adjacent to the light-transmitting region 1011, and the second pixel units 103 are driven by the second driving circuit 1023.

The light-emitting device 1012 includes at least one of a mini light-emitting diode and a micro light-emitting diode.

Further, the light-emitting device 1012 is the micro light-emitting diode. In the step S20, the light-emitting device on a growth substrate or on an intermediate substrate is transferred to the first driving circuit 1021 by a mass transfer method, such as electromagnetic force, electrostatic force, and Van der Waals forces. A thickness of the light-emitting device 1012 is greater than or equal to 1 μm and less than or equal to 5 μm. Further, the thickness of the light-emitting device 1012 is equal to 3 μm.

An area of the first display region 100a is less than or equal to 30 mm×30 mm. Further, the area of the first display region 100a is less than or equal to 10 mm×10 mm, so that a desirable transfer yield rate in the first portion 102a and the cost control are achieved when the light-emitting device 1012 is manufactured by the mass transfer method in the first portion 102a. Moreover, the quantity of the light-emitting device 1012 required to be manufactured in the first portion 102a also affects the yield rate and the product cost of the light-emitting device 1012. In the case that the quantity of the light-emitting device 1012 required to be manufactured in the first portion 102a is less and the area of the first display region 100a is small, the yield rate of the light-emitting device 1012 manufactured by the mass transfer method in the first portion is high, which is advantageous for cost control. The quantity of the light-emitting device 1012 required to be manufactured in the first portion may be designed according to the actual design requirements. Those skilled in the art can design according to the actual design requirements, which is not redundantly described here.

The electric connecting wire 1022 is formed by a deposition process. The deposition process includes electroplating, electroless plating, printing, evaporation, sputtering, etc. Specifically, in the step S30, an entire electric connecting wire layer is formed on a side of the light-emitting device 1012 away from the first substrate 102, and then the electric connecting wire 1022 is manufactured by a yellow light process. In the step S30, a metal mask is provided, and the electric connecting wire 1022 is formed on surfaces of the light-emitting device 1012 and the first driving circuit 1021 by the metal mask.

Furthermore, the electric connecting wire 1022 may also be formed by a photoresist stripping method. Specifically, in the step S30, an entire photoresist layer is formed on a side of the light-emitting device 1012 away from the first substrate 102, the photoresist layer is then patterned, the electric connecting wire 1022 is manufactured by the deposition process, and the remaining photoresist layer is finally removed.

The electric connecting wire 1022 is located in the same layer with a conductive layer of the second driving circuit 1023, and a material of the electric connecting wire 1022 is the same as a material of the conductive layer. A manufacturing material of the electric connecting wire 1022 includes at least one of titanium (Ti), aluminum (Al), molybdenum (Mo), and indium tin oxide (ITO).

The thickness of the electric connecting wire 1022 may be maintained in a nano-scale thickness since the electric connecting wire 1022 is formed by the deposition process. Specifically, a size of a section of the electric connecting wire 1022 is greater than or equal to 100 nm and less than or equal to 1000 nm. If the second pixel units 1023 are liquid crystal display units, a cell spacing between the first substrate 102 and the second substrate 104 after undergoing the cell forming process is greater than or equal to 1 μm and less than or equal to 5 μm. Further, the cell spacing between the first substrate 102 and the second substrate 104 after undergoing the cell forming process is equal to 3 μm, so as to reduce the effect on the light transmittance of the display panel.

If the second pixel units 1023 are liquid crystal units 1023, the manufacturing method further includes steps as below:

In step S40, providing the second substrate 104, wherein the second substrate 104 and the first substrate undergoes the cell-forming process, the liquid crystal molecules 106 are injected between the first substrate 102 and the second substrate 104, a portion of the second substrate 104 corresponding to the second portion 102b includes a color filter unit 1041, and the liquid crystal molecules 106 are located in the region defined by a sealant 107;

In step S50, manufacturing a first polarizer 1051 on a side of the first substrate 102 away from the second substrate 104, and forming a second polarizer 1052 on a side of the second substrate 104 away from the first substrate 102, wherein a portion of the first polarizer 1051 corresponding to the first portion 102a is provided with a plurality of through-holes; and

In step S60, manufacturing a backlight module 108 on a side of the first polarizer 1051 away from the second substrate 104, wherein a portion of the backlight module 108 corresponding to the first portion 102a is provided with the plurality of through-holes, as shown in FIG. 5D.

In the existing process, the first substrates 102 are generally formed on a piece of a large board. However, when the light-emitting device 1012 is a micro light-emitting diode, the light-emitting device formed on the large board by the mass transfer method is difficult. Therefore, the first driving circuit 1021 and the second driving circuit 1023 are firstly formed in the region of the large board corresponding to the first substrate 102, the first substrate 102 is then cut on the large board according to the design specifications, the light-emitting device 1012 is then formed on the first portion 102a of the first substrate 102 by the mass transfer method, and the electric connecting wire 1022 is formed by the deposition process. Finally, the second substrate 104 which is cut and obtained according to the design specifications and the first substrate 102 undergo the cell-forming process by the cell-forming technique at a chip level, so as to reduce the difficulty of the manufacturing process and ensure the product yield.

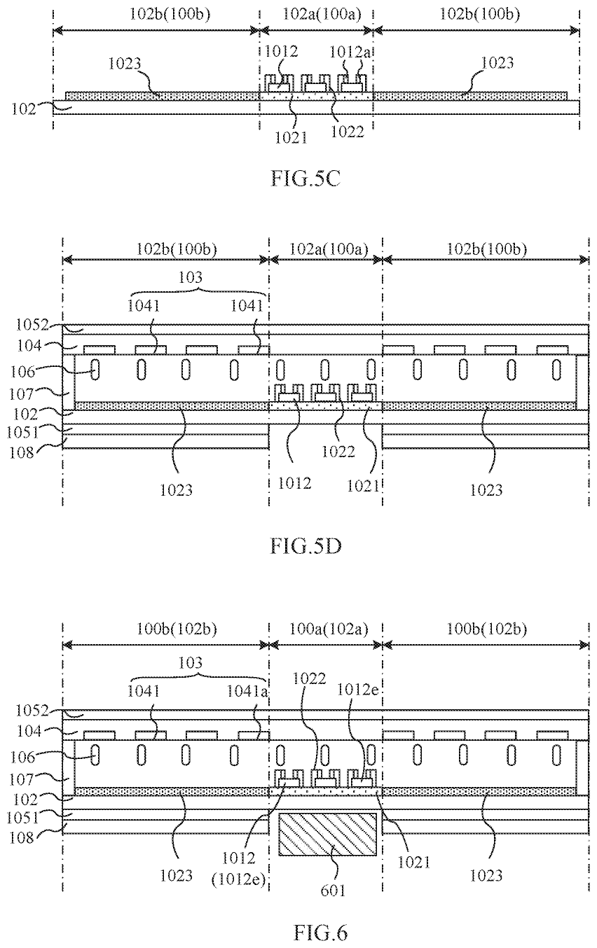

Please refer to FIG. 6, which is a schematic view of a structure of a display apparatus provided by an embodiment of the present disclosure. A display apparatus is further provided by the present disclosure. The display apparatus includes the display panel or the display panel manufactured by the manufacturing method stated above, and a sensor 601, wherein the sensor 601 faces the first display region 100a.

The sensor 601 includes a fingerprint recognition sensor, a camera, a structured light sensor, a time of flight sensor, a distance sensor, a light sensor, etc.

At any time, the sensor 601 can collect signals through the light-transmitting region 1011 to realize various under-screen sensing solutions such as under-screen fingerprint recognition, under-screen camera, under-screen face recognition, and under-screen distance perception. The light-emitting device 1012 may ensure the normal display of the first display region 100a, so that the under-screen sensing technique overlapping the optical display in space of the display panel is achieved, and a full-screen design is realized. Furthermore, a part of the first pixel units 101 in the first display region 100a or the first display regions 100a can also be used as fill lights or indicating lights and other functions.

Further, the display apparatus further includes a touch panel, wherein the touch panel is combined with the display panel in a built-in form or in an external-mounting form, so that the display device has the touch function.

A display panel, a manufacturing method thereof, and a display apparatus are provided in the embodiments of the present disclosure. The display panel includes a first display region 100a. The display panel includes: a plurality of first pixel units 101 located within the first display region 100a, wherein each of the first pixel units 101 includes a light-transmitting region 1011 and a light-emitting device 1012 disposed adjacent to the light-transmitting region 1011; and

a first substrate 102 including a first portion 102a located within the first display region 100a, wherein the first portion 102a includes a first driving circuit 1021 and an electric connecting wire 1022 located on the first driving circuit 1021.

The light-emitting device 1012 is mounted on the first portion 102a, the light-emitting device 1012 includes a plurality of electrodes 1012a away from the first driving circuit 1021, and each of the electrodes 1012a is electrically connected to the first driving circuit 1021 by the electric connecting wire 1022, so that the under-screen sensing technique overlapping the optical display in space of the display panel is achieved, and a thickness of the display panel is reduced. In the display apparatus manufactured by the display panel, the under-screen sensing technique overlapping the optical display in space of the display panel is also achieved, and a thickness of the display panel is also reduced.

In the embodiments above, the description of each embodiment has its own emphasis. For a part that is not specifically described in a certain embodiment, please refer to the relevant description of other embodiments.

The display panel, the manufacturing method thereof, and the display apparatus provided by the embodiments of the present disclosure are described in detail as above. The principles and embodiments of the present disclosure are described in the specific examples. The description of the embodiments is only for helping understand the technical solutions and its core idea of the present disclosure. It should be understood by those skilled in the art that they can still modify the technical solutions described in the above embodiments or equivalently replace some of the technical features, and these modifications or replacements do not depart from the scope of the technical solutions of the embodiments of the present disclosure.

What is claimed is:

1. A display panel, comprising a first display region, wherein the display panel comprises:
a plurality of first pixel units located within the first display region, wherein each of the first pixel units comprises a light-transmitting region and a light-emitting device disposed adjacent to the light-transmitting region;
a first substrate comprising a first portion located within the first display region, wherein the first portion comprises a first driving circuit and an electric connecting wire located on the first driving circuit;
wherein the light-emitting device is mounted on the first portion, the light-emitting device comprises a plurality of electrodes away from the first driving circuit, and each of the electrodes is electrically connected to the first driving circuit by the electric connecting wire.

2. The display panel as claimed in claim 1, wherein the light-emitting device is a self-illuminating display device.

3. The display panel as claimed in claim 2, wherein the light-emitting device comprises at least one of a mini light-emitting diode and a micro light-emitting diode.

4. The display panel as claimed in claim 1, wherein the light-emitting device further comprises a main body mounted on the first substrate, the electrodes extended from the main body, and the electric connecting wire extended along a surface of the main body.

5. The display panel as claimed in claim 4, wherein each of the electrodes comprises a first electrode and a second electrode extended from the main body; the electric connecting wire comprises a first wire and a second wire, the first wire electrically connects the first electrode with the first driving circuit, and the first wire is extended along the surface of the main body; the second wire electrically connects the second electrode with the first driving circuit, and the second wire is extended along the surface of the main body.

6. The display panel as claimed in claim 1, wherein a manufacturing material of the electric connecting wire comprises one of titanium (Ti), aluminum (Al), molybdenum (Mo), and indium tin oxide (ITO).

7. The display panel as claimed in claim 1, wherein a size of a section of the electric connecting wire is greater than or equal to 100 nm and less than or equal to 1000 nm.

8. The display panel as claimed in claim 1, wherein the display panel further comprises a second display region arranged adjacent to the first display region, and the display panel further comprises a plurality of second pixel units located within the second display region, wherein a luminous mode of the second pixel units is different from a luminous of the first pixel units.

9. The display panel as claimed in claim 8, wherein each of the second pixel units is a liquid crystal display pixel unit.

10. The display panel as claimed in claim 9, wherein the first substrate further comprises a second portion located within the second display region; the second portion comprises a second driving circuit, and the second driving circuit is used to drive the second pixel units.

11. The display panel as claimed in claim 10, wherein the electric connecting wire is located in the same layer with a conductive layer of the second driving circuit, and a material of the electric connecting wire is the same as a material of the conductive layer.

12. The display panel as claimed in claim 11, wherein the conductive layer comprises a pixel electrode, and the electric connecting wire is located in the same layer with the pixel electrode and the material of the conductive layer is the same as a material of the pixel electrode.

13. The display panel as claimed in claim 10, wherein the display panel further comprises a second substrate disposed opposite the first substrate, and a portion of the second substrate corresponding to the second portion comprises a plurality of color filter units.

14. The display panel as claimed in claim 13, wherein the display panel further comprises:
a first polarizer disposed on a side of the first substrate away from the second substrate, wherein a portion of the first polarizer corresponding to the first portion is provided with a plurality of through-holes; and
a second polarizer disposed on a side of the second substrate away from the first substrate.

15. The display panel as claimed in claim 14, wherein the display panel further comprises:
a backlight module disposed on a side of the first polarizer away from the first substrate, wherein a portion of the backlight module corresponding to the first portion is provided with the plurality of through-holes.

16. The display panel as claimed in claim 1, wherein in a top view, an area of the light-emitting device is less than or equal to an area of the light-transmitting region.

17. A manufacturing method for a display panel, comprising steps as below:
S10, forming a first substrate, wherein the first substrate comprises a first portion and a second portion adjacent to the first portion, the first portion comprises a first driving circuit, and the second portion comprises a second driving circuit;
S20, forming a light-emitting device on the first portion, wherein the light-emitting device comprises a plurality of electrodes away from the first driving circuit; and
S30, forming an electric connecting wire by a deposition process, wherein the electric connecting wire electrically connects the electrodes with the first driving circuit;
wherein the first portion of the first substrate corresponds to a first display region of the display panel, the second portion of the first substrate corresponds to a second display region of the display panel adjacent to the first display region, and the display panel comprises a plurality of first pixel units located within the first display region, and a plurality of second pixel units located within the second display region, wherein a luminous mode of the first pixel units is different from a luminous mode of the second pixel units, each of the first pixel units comprises a light-transmitting region and a light-emitting device disposed adjacent to the light-transmitting region, and the second pixel units are driven by the second driving circuit.

18. The manufacturing method as claimed in claim 17, wherein the light-emitting device comprises at least one of a mini light-emitting diode and a micro light-emitting diode.

19. A display apparatus, comprising a display panel and a sensor, wherein the display panel comprises:
a plurality of first pixel units located within a first display region, wherein each of the first pixel units comprises a light-transmitting region and a light-emitting device disposed adjacent to the light-transmitting region; and
a first substrate comprising a first portion located within the first display region, wherein the first portion comprises a first driving circuit and an electric connecting wire located on the first driving circuit;
wherein the light-emitting device is mounted on the first portion, the light-emitting device comprises a plurality of electrodes away from the first driving circuit, and each of the electrodes is electrically connected to the first driving circuit by the electric connecting wire; and the sensor faces to the first display region.

20. The display apparatus as claimed in claim 19, wherein the sensor comprises at least one of a fingerprint recognition sensor, a camera, a structured light sensor, a time of flight sensor, a distance sensor, and a light sensor.
